(19) United States
(12) Patent Application Publication
(10) Pub. No.: US 2016/0225978 A1
(43) Pub. Date: Aug. 4, 2016

(54) METHOD OF MANUFACTURING VIBRATION DEVICE

(71) Applicant: Seiko Epson Corporation, Tokyo (JP)

(72) Inventors: Takahiro Kan, Minowa (JP); Kenichi Otsuki, Minowa (JP); Takumi Suzuki, Minowa (JP); Masayuki Ishikawa, Suwa (JP); Shigeru Shiraishi, Ina (JP); Go Yamashita, Ina (JP)

(21) Appl. No.: 15/006,388

(22) Filed: Jan. 26, 2016

(30) Foreign Application Priority Data
Feb. 3, 2015 (JP) 2015-019619
Mar. 19, 2015 (JP) 2015-055792

(51) Int. Cl. H01L 41/253

(52) U.S. Cl. CPC H01L 41/253

(57) ABSTRACT

A method of manufacturing a vibration device includes a process of strongly exciting a vibrator element by applying power, which is higher than drive power during use of the vibrator element, to the vibrator element, and a process of adjusting a frequency of the vibrator element after the process of strongly exciting the vibrator element.

### BACKGROUND

1. Technical Field

The present invention relates to a method of manufacturing a vibration device.

2. Related Art

In a process of manufacturing a vibrator on which a quartz crystal vibrator element is mounted, typically, after mounting the quartz crystal vibrator element on a package base, a frequency adjustment process of adjusting a frequency with respect to individual quartz crystal vibrator elements is carried out.

For example, JP-A-2009-44237 discloses a method in which after mounting the vibrator element on a package base, apart of an excitation electrode is etched through ion milling in which the excitation electrode is irradiated with an ion laser and the like, thereby carrying out frequency adjustment of the vibrator.

However, in the frequency adjustment process, even in a vibrator element having no problem in external appearance, there is a problem in that when the vibrator element does not resonate, the vibrator element becomes a defective product, and thus a yield ratio decreases.

### SUMMARY

An advantage of some aspects of the invention is to provide a method of manufacturing a vibration device capable of improving a yield ratio during manufacturing.

The invention can be implemented as the following forms or application examples.

### Application Example 1

A method of manufacturing a vibration device according to this application example includes strongly exciting a vibrator element by applying power, which is higher than drive power during use of the vibrator element, to the vibrator element, and adjusting a frequency of the vibrator element after the strongly exciting of the vibrator element.

In the method of manufacturing the vibration device, since the frequency adjustment of the vibrator element is carried out after strongly exciting the vibrator element, as described later, it is possible to reduce an equivalent series resistance value (CI value) of the vibrator element in a frequency adjustment process, and it is possible to improve an oscillation rate. Accordingly, according to the method of manufacturing the vibration device as described above, it is possible to improve a yield ratio during manufacturing of the vibration device.

### Application Example 2

The method of manufacturing the vibration device according to the application example may further include forming the vibrator element in a substrate before the strongly exciting of the vibrator element.

The method of manufacturing the vibration device as described above includes the forming of the vibrator element in a substrate. Accordingly, it is possible to strongly excite the vibrator element, for example, in a state in which the vibrator element is formed in the substrate. In other words, in the method of manufacturing the vibration device, it is possible to strongly excite the vibrator element before the vibrator element is accommodated in a container.

According to this, in the method of manufacturing the vibration device, it is possible to reduce a possibility that foreign matter, which is attached to the vibrator element, enters the container of the vibration device.

### Application Example 3

In the method of manufacturing the vibration device according to the application example, the strongly exciting of the vibrator element may include inspecting the vibrator element.

In the method of manufacturing the vibration device as described above, the inspecting is included in the process of strongly exciting the vibrator element, and thus it is possible to reduce transportation of a defective vibrator element that occurs in the strongly exciting process to the subsequent process.

Accordingly, it is possible to realize a reduction in a defective percentage in finished products of the vibration device, and thus it is possible to realize a reduction in the failure cost.

### Application Example 4, Application Example 5

In the method of manufacturing the vibration device according to the application examples, a plurality of the vibrator elements may be formed in the substrate.

In the method of manufacturing the vibration device as described above, the vibrator elements are formed by using a so-called wafer substrate, and the strongly exciting is carried out, and thus it is possible to attain high productivity.

### Application Example 6, Application Example 7

In the method of manufacturing the vibration device according to the application examples, the strongly exciting of the vibrator element may be carried out with respect to the plurality of vibrator elements which are formed in the substrate.

In the method of manufacturing the vibration device as described above, the strongly exciting of the vibrator element is carried out with respect to the plurality of vibrator elements which are formed in the substrate, and thus it is possible to attain high productivity.

### Application Example 8

The method of manufacturing the vibration device according to the application example may further include joining the base and the vibrator element through a joining member before the strongly exciting of the vibrator element.

The method of manufacturing the vibration device as described above includes the joining of the base and the vibrator element through a joining member before the strongly exciting of the vibrator element, and thus it is possible to improve a yield ratio during manufacturing of the vibration device.

Application Example 9, Application Example 10, Application Example 11, Application Example 12

In the method of manufacturing the vibration device according to the application examples, in the strongly exciting of the vibrator element, power of 2.5 mW or more to 100 mW or less may be applied to the vibrator element.

In the method of manufacturing the vibration device as described above, as described later, it is possible to reduce the CI value of the vibrator element in the frequency adjustment process, and it is possible to improve an oscillation rate.

### Application Example 13, Application Example 14, Application Example 15, Application Example 16

In the method of manufacturing the vibration device according to the application examples, the vibrator element may include a quartz crystal substrate including a vibration portion that vibrates with thickness shear vibration.

In the method of manufacturing the vibration device as described above, it is possible to improve a yield ratio during manufacturing of the vibrator.

### Application Example 17

A method of manufacturing a vibration device according to this application example includes forming a vibrator element, joining a base and the vibrator element through a joining member, joining the base and a semiconductor device through a joining member, and applying power, which is higher than drive power during use of the vibrator element, to the vibrator element for strongly exciting before the joining of the semiconductor device.

In the method of manufacturing the vibration device as described above, it is possible to improve a yield ratio during manufacturing of an oscillator. In addition, in the method of manufacturing the oscillator, the vibrator element can also be strongly excited before the vibrator element is accommodated in a container, and thus it is possible to reduce a possibility that foreign matter, which is attached to the vibrator element, enters the container.

### BRIEF DESCRIPTION OF THE DRAWINGS

The invention will be described with reference to the accompanying drawings, wherein like numbers reference like elements.

FIG. 1A is a cross-sectional view schematically illustrating a vibrator according to a first embodiment, and FIG. 1B is a plan view schematically illustrating the vibrator according to the first embodiment.

FIG. 2 is a perspective view schematically illustrating a vibrator element of the vibrator according to the first embodiment.

FIG. 3 is a plan view schematically illustrating the vibrator element of the vibrator according to the first embodiment.

FIG. 4 is a cross-sectional view schematically illustrating the vibrator element of the vibrator according to the first embodiment.

FIG. 5 is a cross-sectional view schematically illustrating the vibrator element of the vibrator according to the first embodiment.

FIG. 6 is a perspective view schematically illustrating an AT-cut quartz crystal substrate.

FIG. 7 is a cross-sectional view schematically illustrating the vibrator element of the vibrator according to the first embodiment.

FIG. 8 is a flowchart illustrating an example of a method of manufacturing the vibrator according to the first embodiment.

FIG. 9 is a cross-sectional view schematically illustrating a process of manufacturing the vibrator according to the first embodiment.

FIG. 10 is a graph illustrating a relationship between a drive level and a variation ratio of a CI value.

FIG. 11 is a graph illustrating a relationship between the drive level and an oscillation rate.

FIGS. 12A and 12B illustrate a vibrator that is obtained by a method of manufacturing the vibrator according to a second embodiment, FIG. 12A is an external appearance plan view, and FIG. 12B is a cross-sectional view taken along line A-A′ in FIG. 12A.

FIGS. 13A to 13C are flowcharts illustrating the method of manufacturing the vibrator according to the second embodiment.

FIGS. 14A to 14D illustrate a process of forming a vibrator element of the vibrator according to the second embodiment, FIG. 14A is an external appearance perspective view of a wafer including a plurality of vibration elements, FIG. 14B is an enlarged plan view of a B portion in FIG. 14A, and FIGS. 14C and 14D are enlarged plan views illustrating a state in which an electrode is formed in each of the vibration elements.

FIGS. 15A and 15B are external appearance perspective views illustrating a process of strongly exciting the vibrator according to the second embodiment.

FIGS. 16A to 16C are cross-sectional views illustrating a process of accommodating the vibrator according to the second embodiment.

FIGS. 17A and 17B illustrate an oscillator obtained by a method of manufacturing the oscillator according to a third embodiment, FIG. 17A is an external appearance plan view, and FIG. 17B is a cross-sectional view taken along line C-C′ in FIG. 17A.

FIG. 18 is a flowchart illustrating the method of manufacturing the oscillator according to the third embodiment.

FIGS. 19A to 19C are cross-sectional views illustrating a process of accommodating the oscillator according to the third embodiment.

### DESCRIPTION OF EXEMPLARY EMBODIMENTS

Hereinafter, preferred embodiments of the invention will be described in detail with reference to the accompanying drawings. In addition, the following embodiments are not intended to limit the contents of the invention which are described in the appended claims. In addition, it cannot be said that all of configurations to be described later are indispensable constitutional requirements of the invention.

### First Embodiment

### 1. Vibrator

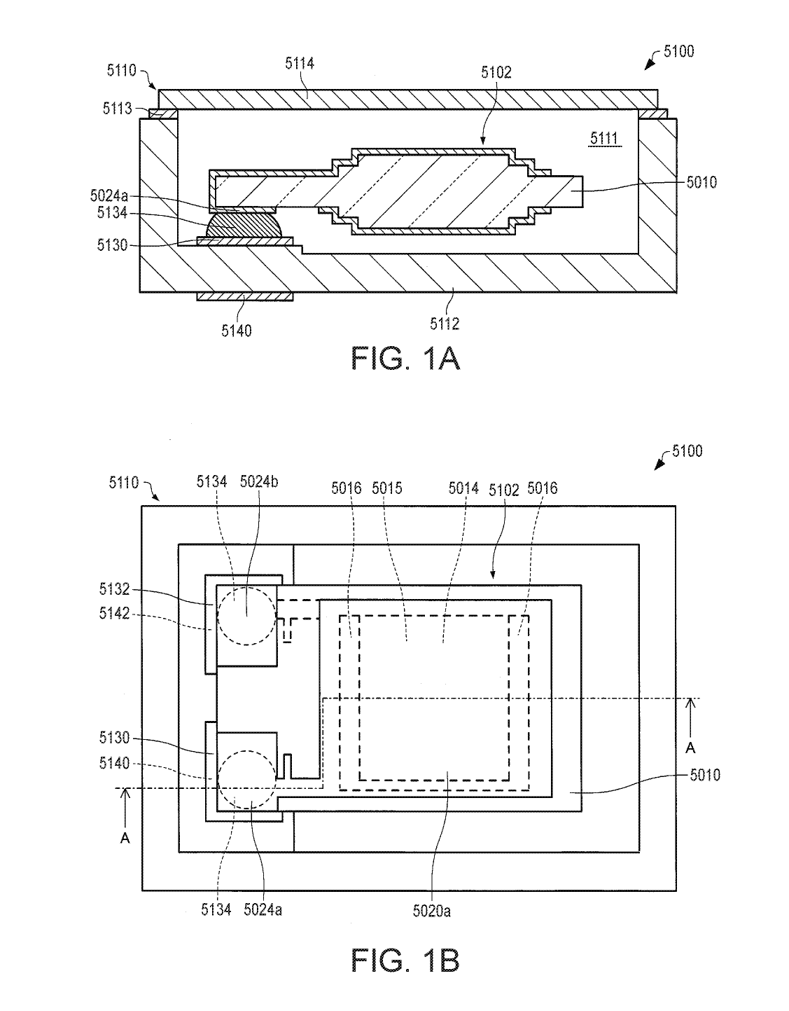

First, description will be given of a vibrator that becomes an object for carrying out a method of manufacturing a vibrator (example of a vibration device) according to this embodiment with reference to the drawings. FIG. 1A is a cross-sectional view schematically illustrating a vibrator 5100 according to this embodiment. FIG. 1B is a plan view schematically illustrating the vibrator 5100 according to this embodiment. In addition, FIG. 1A is a cross-sectional view taken along line A-A in FIG. 1B.

As illustrated in FIGS. 1A and 1B, the vibrator 5100 includes a vibrator element 5102 and a package 5110. Hereinafter, the vibrator element 5102 and the package 5110 will be described in detail.

### (1) Vibrator Element

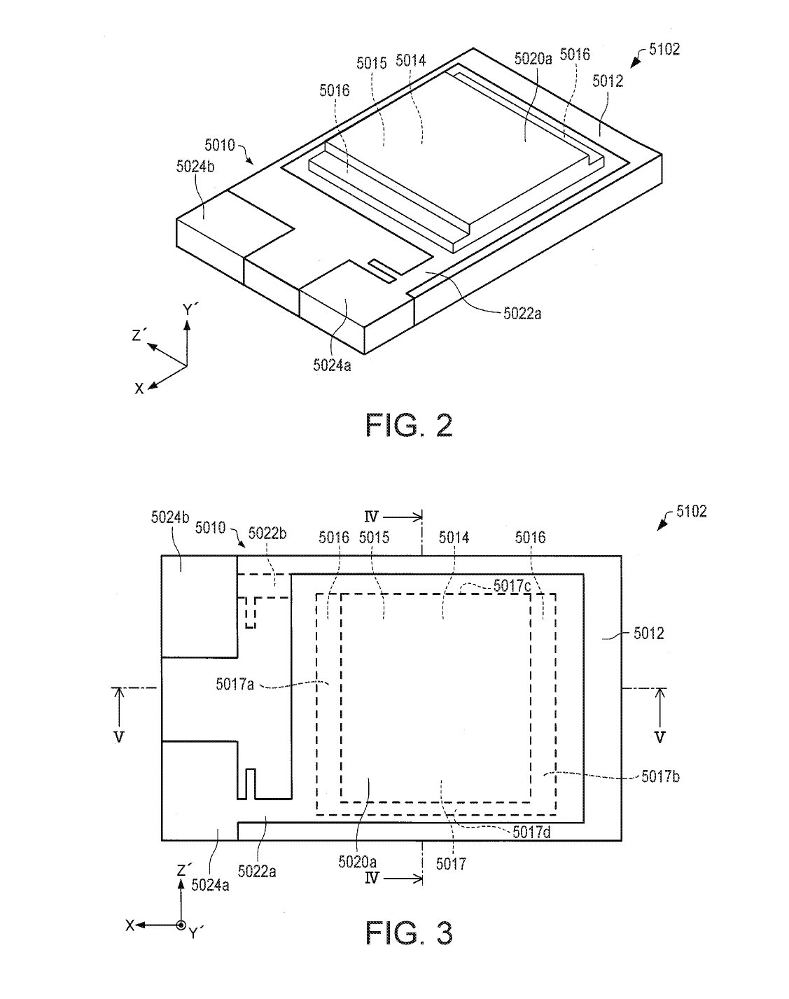

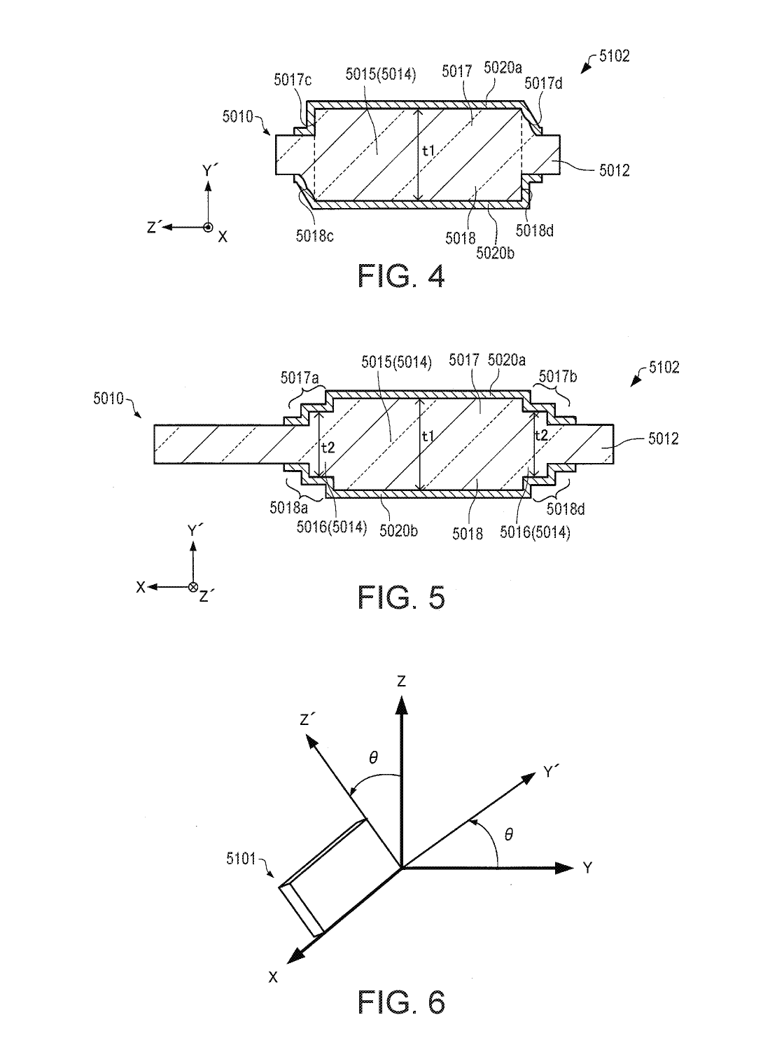

FIG. 2 is a perspective view schematically illustrating the vibrator element 5102. FIG. 3 is a plan view schematically illustrating the vibrator element 5102. FIG. 4 is a cross-sectional view schematically illustrating the vibrator element 5102 taken along line IV-IV in FIG. 3. FIG. 5 is a cross-sectional view schematically illustrating the vibrator element 5102 taken along line V-V in FIG. 3.

As illustrated in FIGS. 2 to 5, the vibrator element 5102 includes a quartz crystal substrate 5010, and excitation electrodes 5020a and 5020b.

The quartz crystal substrate 5010 is constituted by an AT-cut quartz crystal substrate. Here, FIG. 6 is a perspective view schematically illustrating an AT-cut quartz crystal substrate 5101.

Typically, a piezoelectric material such as quartz crystal is a trigonal system, and has crystal axes (X, Y, Z) as illustrated in FIG. 6. The X axis represents an electrical axis, the Y axis represents a mechanical axis, and the Z axis represents an optical axis. A quartz crystal substrate 5101 is a flat plate of a so-called rotated Y-cut quartz crystal substrate in which an XZ plane (plane including the X axis and the Z axis) is cut from a piezoelectric material (for example, a synthetic quartz crystal) along a plane rotated around the X axis by an angle θ. In addition, the Y axis and the Z axis are also rotated around the X axis by the angle θ and are set to a Y′ axis and a Z′ axis, respectively. The quartz crystal substrate 5101 is a substrate in which a plane including the X axis and the Z′ axis is set as a main surface, and a direction along the Y′ axis is set as a thickness direction. Here, when θ is set to 35°15′, the quartz crystal substrate 5101 becomes the AT-cut quartz crystal substrate. Accordingly, in the AT-cut quartz crystal substrate 5101, an XZ′ plane (plane including the X axis and the Z′ axis) orthogonal to the Y′ axis becomes a main surface (main surface of a vibration portion), and the AT-cut quartz crystal substrate 5101 can vibrate in a state in which thickness shear vibration is set as main vibration. The quartz crystal substrate 5010 can be obtained by processing the AT-cut quartz crystal substrate 5101.

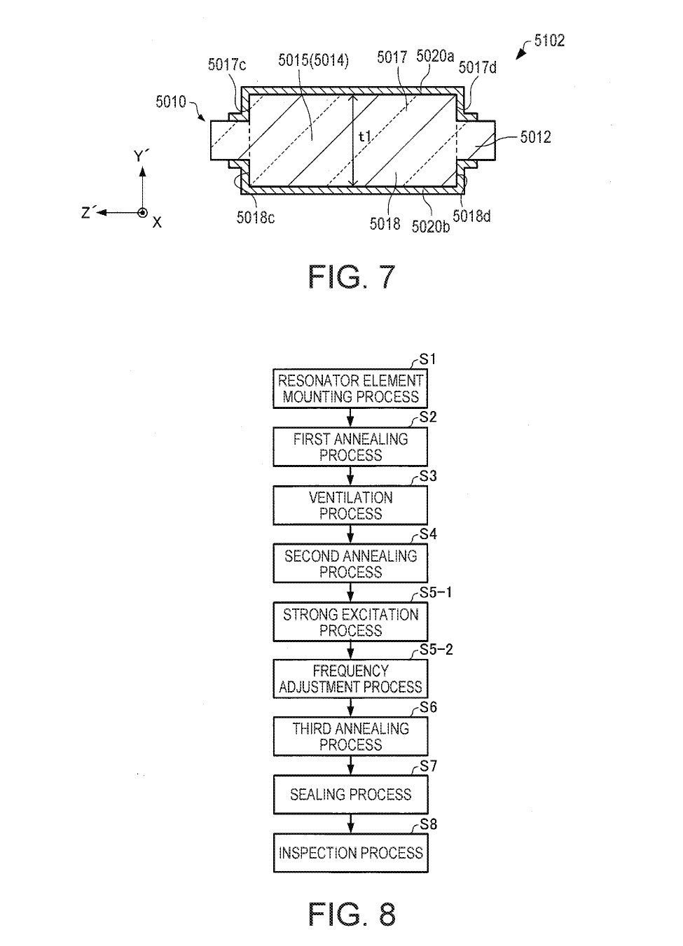

As illustrated in FIG. 6, the quartz crystal substrate 5010 is constituted by the AT-cut quartz crystal substrate 5101. In the AT-cut quartz crystal substrate 5101, the X axis of an orthogonal coordinate system including crystal axes of the quartz crystal such as the X axis set as the electrical axis, the Y axis set as the mechanical axis, and the Z axis set as the optical axis is set as a rotation axis, an axis, which is obtained by inclining the Z axis in such a manner that a +Z side is rotated in a −Y direction, is set as the Z′ axis, an axis, which is obtained by inclining the Y axis in such a manner that a +Y side is rotated in a +Z direction, is set as the Y′ axis, a plane including the X axis and the Z′ axis is set as a main surface, and a direction along the Y′ axis is set as a thickness direction. In addition, in FIGS. 2 to 5, and in FIG. 7, the X axis, the Y′ axis, and the Z′ axis which are orthogonal to each other are illustrated.

In addition, the quartz crystal substrate 5010 is not limited to the AT-cut quartz crystal substrate 5101, and may be an SC-cut quartz crystal substrate in which thickness shear vibration is excited, and a piezoelectric substrate such as a BT-cut quartz crystal substrate that vibrates with different thickness shear vibration.

For example, the quartz crystal substrate 5010 has a rectangular shape in which the Y′ axis direction is set as a thickness direction, and the X axis direction is set as a long side and the Z′ axis direction is set as a short side in a plan view from the Y′ axis direction (hereinafter, simply referred to as “in a plan view”). The quartz crystal substrate 5010 includes a peripheral portion 5012 and a vibration portion 5014.

The peripheral portion 5012 is provided at the periphery of the vibration portion 5014. The peripheral portion 5012 is provided along an outer edge of the vibration portion 5014. The peripheral portion 5012 has a thickness smaller than that of the vibration portion 5014.

The vibration portion 5014 is surrounded by the peripheral portion 5012 in a plan view, and has a thickness larger than that of the peripheral portion 5012. The vibration portion 5014 has a side along the X axis, and a side along the Z′ axis. Specifically, in a plan view, the vibration portion 5014 has a rectangular shape in which the X axis direction is set as the long side, and the Z′ axis direction is set as the short side. The vibration portion 5014 includes a first portion 5015 and a second portion 5016.

The first portion 5015 of the vibration portion 5014 has a thickness larger than that of the second portion 5016. In an example illustrated, the first portion 5015 is a portion having a thickness t1. In a plan view, the first portion 5015 has a square shape.

The second portion 5016 of the vibration portion 5014 has a thickness smaller than that of the first portion 5015. In the example illustrated, the second portion 5016 is a portion having a thickness t2. The second portion 5016 is provided in the +X axis direction and the −X axis direction of the first portion 5015, respectively. That is, the first portion 5015 is interposed between the second portions 5016 in the X axis direction. As described above, the vibration portion 5014 includes two kinds of portions 5015 and 5016 which have thicknesses different from each other, and the vibrator element 5102 has a two-step type mesa structure.

The vibration portion 5014 can vibrate in a state in which the thickness shear vibration is set as main vibration. Since the vibration portion 5014 has the two-step type mesa structure, the vibrator element 5102 can have an energy confinement effect. In addition, the “thickness shear vibration” represents vibration in which a displacement direction of the quartz crystal substrate is parallel to the main surface of the quartz crystal substrate (in the example illustrated, the displacement direction of the quartz crystal substrate is the X axis direction), and a propagation direction of waves is a plate thickness direction.

The vibration portion 5014 includes a first convex portion 5017 that further protrudes in the +Y′ axis direction in comparison to the peripheral portion 5012, and a second convex portion 5018 that further protrudes in the −Y′ axis direction in comparison to the peripheral portion 5012. For example, the convex portions 5017 and 5018 have the same shape and the same size. The convex portions 5017 and 5018 include the first portion 5015 and the second portion 5016.

For example, as illustrated in FIG. 5, a lateral surface 5017a in the +X axis direction and a lateral surface 5017b in the −X axis direction in the first convex portion 5017, and a lateral surface 5018a in the +X axis direction and a lateral surface 5018b in the -X axis direction in the second convex portion 5018 are provided with two step differences due to a difference between the thickness of the first portion 5015 and the thickness of the second portion 5016, or a difference between the thickness of the second portion 5016 and the thickness of the peripheral portion 5012.

For example, as illustrated in FIG. 4, a lateral surface 5017c of the first convex portion 5017 in the +Z′ axis direction is a surface that is perpendicular to a plane including the X axis and the Z′ axis. For example, a lateral surface 5017d of the first convex portion 5017 in the −Z′ axis direction is a surface that is inclined to the plane including the X axis and the Z′ axis.

For example, as illustrated in FIG. 4, a lateral surface 5018c of the second convex portion 5018 in the +Z′ axis direction is a surface that is inclined to the plane including the X axis and the Z′ axis. A lateral surface 5018d of the second convex portion 5018 in the −Z′ axis direction is a surface that is perpendicular to the plane including the X axis and the Z′ axis.

For example, in a case where the AT-cut quartz crystal substrate is etched by using a solution containing a hydrofluoric acid as an etchant, an m-plane of a quartz crystal is exposed, and thus the lateral surface 5017d of the first convex portion 5017 and the lateral surface 5018c of the second convex portion 5018 become surfaces which are inclined to the plane including the X axis and the Z′ axis. In addition, although not illustrated, a lateral surface of the quartz crystal substrate 5010 in the −Z′ direction other than the lateral surfaces 5017d and 5018c may be surfaces which are inclined with respect to the plane including the X axis and the Z′ axis through exposure of the m plane of the quartz crystal.

In addition, as illustrated in FIG. 7, the lateral surfaces 5017d and 5018c may be surfaces which are perpendicular to the plane including the X axis and the Z′ axis. For example, the lateral surfaces 5017d and 5018c may become surfaces which are perpendicular to the plane including the X axis and the Z′ axis by processing the AT-cut quartz crystal substrate with a laser, or by etching the AT-cut quartz crystal substrate through dry etching. In addition, FIG. 2 illustrates a case where the lateral surfaces 5017d and 5018c are surfaces which are perpendicular to the plane including the X axis and the Z′ axis for convenience.

The first excitation electrode 5020a and the second excitation electrode 5020b are provided to overlap the vibration portion 5014 in a plan view. In the example illustrated, the excitation electrodes 5020a and 5020b are also further provided to the peripheral portion 5012. For example, a planar shape (shape when seen in the Y′ axis direction) of the excitation electrodes 5020a and 5020b is a rectangular shape. The vibration portion 5014 is provided on an inner side of the outer edge of the excitation electrodes 5020a and 5020b in a plan view. That is, the area of the excitation electrodes 5020a and 5020b in a plan view is larger than that of the vibration portion 5014. The excitation electrodes 5020a and 5020b are electrodes configured to apply a voltage to the vibration portion 5014.

The first excitation electrode 5020a is connected to a first electrode pad 5024a through a first lead-out electrode 5022a. The second excitation electrode 5020b is connected to a second electrode pad 5024b through a second lead-out electrode 5022b. The electrode pads 5024a and 5024b are provided in the +X axis direction of the peripheral portion 5012. As the excitation electrodes 5020a and 5020b, the lead-out electrodes 5022a and 5022b, and the electrode pads 5024a and 5024b, for example, electrodes, which are obtained by stacking chromium and gold from a quartz crystal substrate 5010 side in this order, may be used.

In addition, description has been given of an example in which the area of the excitation electrodes 5020a and 5020b is larger than that of the vibration portion 5014, but the area of the excitation electrodes 5020a and 5020b in a plan view may be smaller than that of the vibration portion 5014. In this case, the excitation electrodes 5020a and 5020b are provided on an inner side of the outer edge of the vibration portion 5014 in a plan view.

In addition, description has been given of the two-step type mesa structure in which the vibration portion 5014 includes two kinds of portions 5015 and 5016 which have thicknesses different from each other, but the number of steps of the mesa structure of the vibrator element 5102 is not particularly limited. For example, the vibrator element 5102 may be a three-step type mesa structure in which the vibration portion includes three kinds of portions which have thicknesses different from each other, or a one-step type mesa structure in which the vibration portion does not include portions having a different thickness. In addition, the vibrator element 5102 is not limited to the mesa type. For example, the quartz crystal substrate 5010 may have a uniform thickness, or may have a bevel structure or a convex structure.

In addition, description has been given of an example in which the lateral surfaces 5017c and 5017d of the first convex portion 5017, and the lateral surfaces 5018c and 5018d of the second convex portion 5018 are not provided with a step difference due to a difference between the thickness of the first portion 5015 and the thickness of the second portion 5016. However, in the vibrator element 5102, a step difference may be provided in the lateral surfaces 5017c, 5017d, 5018c, and 5018d.

In addition, description has been given of an example in which the first convex portion 5017 that further protrudes in the +Y′ axis direction in comparison to the peripheral portion 5012, and the second convex portion 5018 that further protrudes in the −Y′ axis direction in comparison to the peripheral portion 5012 are provided, but the vibrator element 5102 may include any one of the convex portions.

### (2) Package

As illustrated in FIGS. 1A and 1B, the package 5110 includes a box-shaped base 5112 including a concave portion 5111 of which a top surface is opened, and a seal ring 5113 that is disposed on an upper end surface of the base 5112 that surrounds an opening of the concave portion 5111, and a plate-shaped lead 5114 that is joined to the base 5112 so as to cover the opening of the concave portion 5111. In addition, in FIG. 1B, the lead 5114 and the seal ring 5113 are not illustrated for convenience.

The package 5110 has an accommodation space that is formed when the concave portion 5111 is covered with the lead 5114, and the vibrator element 5102 is air-tightly accommodated and provided in the accommodation space. That is, the vibrator element 5102 is accommodated in the package 5110.

In addition, for example, the inside of the accommodation space (the concave portion 5111), in which the vibrator element 5102 is accommodated, may be set to a decompressed state (vacuum state), or an inert gas such as nitrogen, helium, and argon may be sealed in the accommodation space. According to this, vibration characteristics of the vibrator element 5102 are improved.

For example, the material of the base 5112 may be various kinds of ceramic such as an aluminum oxide. For example, the material of the lead 5114 is a material having approximately the same linear expansion coefficient as that of the material of the base 5112. Specifically, in a case where the material of the base 5112 is ceramic, the material of the lead 5114 is an alloy such as Kovar.

A first connection terminal 5130 and a second connection terminal 5132 are provided on the bottom surface of the concave portion 5111 of the package 5110. The first connection terminal 5130 is provided to face the first electrode pad 5024a of the vibrator element 5102. The second connection terminal 5132 is provided to face the second electrode pad 5024b of the vibrator element 5102. The connection terminals 5130 and 5132 are electrically connected to the electrode pads 5024a and 5024b, respectively, through a conductive fixing member 5134.

A first external terminal 5140 and a second external terminal 5142 are provided on the bottom surface of the package 5110. For example, the first external terminal 5140 is provided at a position that overlaps the first connection terminal 5130 in a plan view. For example, the second external terminal 5142 is provided at a position that overlaps the second connection terminal 5132 in a plan view. The first external terminal 5140 is electrically connected to the first connection terminal 5130 through a via (not illustrated). The second external terminal 5142 is electrically connected to the second connection terminal 5132 through a via (not illustrated).

As the connection terminals 5130 and 5132, and the external terminals 5140 and 5142, for example, a metal film, in which respective films of nickel (Ni), gold (Au), silver (Ag), and copper (Cu) are stacked on a metallized layer (base layer) of chromium (Cr) and tungsten (W), is used. As the conductive fixing member 5134, for example, solder, silver paste, a conductive adhesive (adhesive in which conductive filler such as a metal particle is dispersed in a resin material), and the like are used.

### 2. Method of Adjusting Frequency of Vibrator and Method of Manufacturing Vibrator

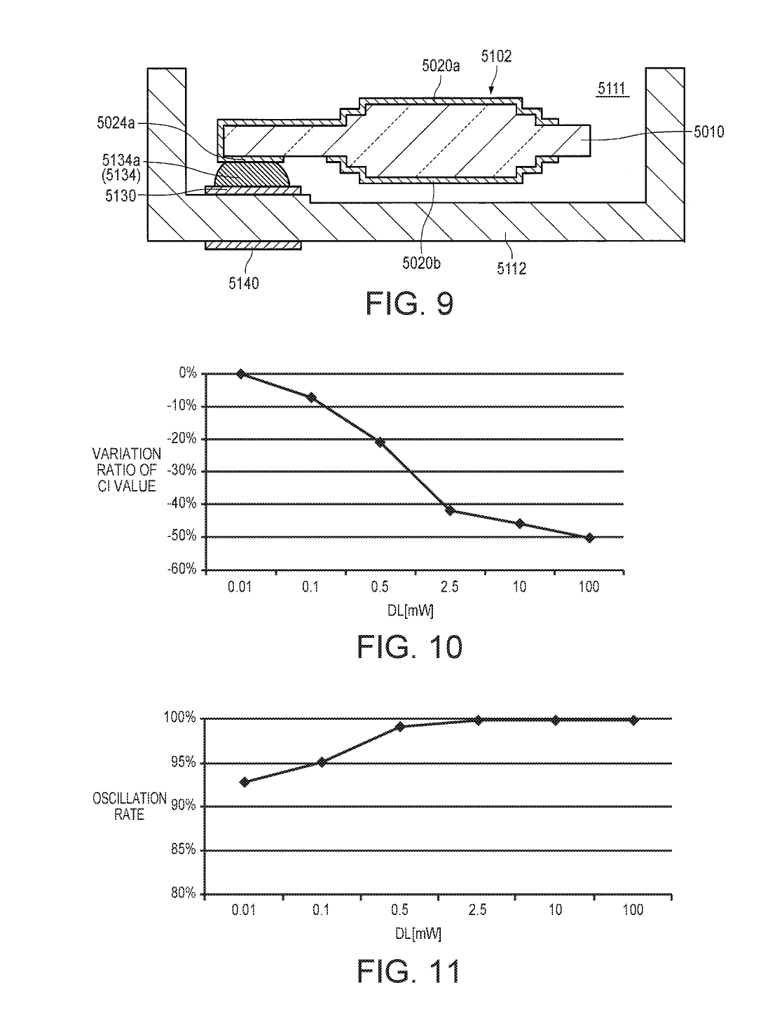

Next, description will be given of a method of adjusting a frequency of the vibrator according to this embodiment and a method of manufacturing the vibrator. FIG. 8 is a flowchart illustrating an example of the method of manufacturing the vibrator according to this embodiment. FIG. 9 is a cross-sectional view schematically illustrating processes of manufacturing the vibrator according to this embodiment.

The method of manufacturing the vibrator according to this embodiment includes the method of adjusting the frequency of the vibrator according to this embodiment. The method of manufacturing the vibrator according to this embodiment in FIG. 8 includes a strong excitation process S5-1 and a frequency adjustment process S5-2 as the method of adjusting the frequency of the vibrator according to this embodiment.

First, as illustrated in FIG. 9, the vibrator element 5102 is mounted on the base 5112 (vibrator element mounting process (joining process) S1).

Specifically, the vibrator element 5102 is fixed (joined) onto the connection terminals 5130 and 5132 which are provided to the base 5112 by using the conductive adhesive (joining member) 5134a.

Then, the conductive adhesive 5134a is dried in a temperature atmosphere of a predetermined temperature (approximately 180° C.), thereby vaporizing a solvent of the conductive adhesive 5134a.

Next, the conductive adhesive 5134a is subjected to a heating treatment (first annealing process S2).

For example, the base 5112 on which the vibrator element 5102 is mounted is introduced into an annealing furnace (not illustrated), and annealing of the conductive adhesive 5134a is carried out at a peak heating temperature of approximately 200° C. to 300° C. In the first annealing process S2, for example, annealing for 4 hours, which includes heating for 2 hours at the peak heating temperature, is carried out. In the first annealing process S2, the conductive fixing member 5134 can be formed by curing the conductive adhesive 5134a.

Here, in the first annealing process S2, annealing may be carried out in a vacuum atmosphere. When annealing is carried out in the vacuum atmosphere, it is possible to reduce the degree of oxidation of the excitation electrodes 5020a and 5020b. According to this, it is possible to suppress deterioration in aging characteristics. This is also true of a second annealing process S4 and a third annealing process S6 to be described later.

Next, the vibrator element 5102 and the conductive fixing member 5134 are cooled down to a predetermined temperature, and the annealing furnace is opened and ventilated (ventilation process S3).

Next, the conductive fixing member 5134 and the vibrator element 5102 are subjected to a heating treatment (second annealing process S4).

For example, the base 5112 on which the vibrator element 5102 is mounted is introduced into the annealing furnace, and a heating treatment is carried out with respect to the vibrator element 5102 and the conductive fixing member 5134. For example, the second annealing process S4 is carried out under the same temperature conditions and the same time conditions as in the first annealing process S2. In the second annealing process S4, discharging of an out-gas component in the conductive fixing member 5134 which is not sufficiently removed with the first annealing process S2, and removal of the out-gas component that is attached to the vibrator element 5102 are carried out, and stress distortion of the vibrator element 5102, which is not completely solved in the first annealing process S2, can be reduced.

Next, power that is higher than drive power during use of the vibrator element 5102 is applied to the vibrator element 5102 so as to strongly excite the vibrator element 5102 (strong excitation process S5-1).

Specifically, as illustrated in FIG. 9, power that is higher than power (drive power during typical operation) during use of the vibrator element 5102 is applied to the excitation electrodes 5020a and 5020b by using a synthesizer, an oscillation circuit for strong excitation, and the like in a state in which the vibrator element 5102 is mounted on the base 5112, thereby strongly exciting the vibrator element 5102 (over-drive). For example, the drive power during use of the vibrator element 5102 is approximately 0.01 mWV. In the strong excitation process S5-1, power of 2.5 mW or more to 100 mW or less is applied to the vibrator element 5102. More preferably, in the strong excitation process S5-1, power of 10 mW or more to 100 mW or less is applied to the vibrator element 5102. For example, an application time is 1 second to 30 seconds. When the vibrator element 5102 is strongly excited as described above, it is possible to reduce equivalent series resistance of the vibrator element 5102, that is, a so-called crystal impedance (CI) value, and thus it is possible to improve an oscillation rate in a frequency adjustment process S5-2 (refer to “3. Experimental Example” to be described later).

Here, a drive level is power for oscillating the vibrator element 5102, and is expressed by P=I²×Re. In addition, I represents a current (effective value) that flows to the vibrator element, and Re represents equivalent series resistance of the vibrator element. The current I, which flows to the vibrator element, can be obtained by acquiring a waveform of a current flowing to the vibrator element by using an oscilloscope, and the like over the oscillation circuit.

Next, frequency adjustment of the vibrator element 5102 (vibrator 5100) is carried out (frequency adjustment process S5-2).

For example, although not illustrated, a probe of a measurement device is brought into contact with the external terminals 5140 and 5142 which are electrically connected to the excitation electrodes 5020a and 5020b, a monitor electrode (not illustrated), and the like to excite the vibrator element 5102, and an output frequency is measured. A drive level at this time is a drive level during typical use of the vibrator element. In addition, in a case where a frequency difference exists between an actual frequency that is measured, and a predetermined frequency, a part of the excitation electrodes 5020a and 5020b is etched (ion-milled) by irradiating the excitation electrodes 5020a and 5020b with an ion laser and the like to reduce a mass, thereby carrying out the frequency adjustment. In addition, the frequency adjustment may be carried out by forming a film on the excitation electrodes 5020a and 5020b so as to increase a mass.

Next, the conductive fixing member 5134 and the vibrator element 5102 are subjected to a heating treatment (third annealing process S6).

For example, the base 5112 on which the vibrator element 5102 is mounted is introduced into an annealing furnace, and a heating treatment is carried out with respect to the vibrator element 5102 and the conductive fixing member 5134. For example, in the third annealing process S6, annealing including heating for 45 minutes at a peak heating temperature of approximately 200° C. to 300° C. is carried out.

According to the third annealing process S6, discharging of the out-gas component in the conductive fixing member 5134 which is not sufficiently removed with the first annealing process S2 and the second annealing process S4, and removal of the out-gas component that is attached to the vibrator element 5102 are carried out, and stress distortion of the vibrator element 5102, which is not completely solved in the first annealing process S2 and the second annealing process S4, can be reduced. In addition, it is possible to reduce stress distortion of the vibrator element 5102 which is newly added in the frequency adjustment process S5-2.

In addition, the third annealing process S6 may not be carried out.

Next, as illustrated in FIG. 1A, the lead 5114 is joined to the base 5112, and the concave portion 5111 of the base 5112 is sealed (sealing process S7). According to this, it is possible to accommodate the vibrator element 5102 in the accommodation space (concave portion 5111) of the package 5110. The joining between the base 5112 and the lead 5114 is carried out in such a manner that the lead 5114 is placed on the seal ring 5113, and the seal ring 5113 is welded to the base 5112 by using, for example, a resistance welder. In addition, the joining between the base 5112 and the lead 5114 is not particularly limited, and may be carried out by using an adhesive, or may be carried out through seam welding.

Next, characteristics of the vibrator 5100 are inspected (inspection process S8).

For example, although not illustrated, characteristics (drive level dependence (DLD) characteristics and the like) of the vibrator 5100 are measured by bringing a probe of a measurement device into contact with the external terminals 5140 and 5142 which are electrically connected to the excitation electrodes 5020a and 5020b, a monitor electrode (not illustrated), and the like.

Through the above-described processes, it is possible to manufacture the vibrator 5100.

For example, the method of adjusting the frequency of the vibrator 5100 according to this embodiment has the following characteristics.

The method of adjusting the frequency of the vibrator 5100 according to this embodiment includes the process S5-1 of strongly exciting the vibrator element 5102 by applying power that is higher than drive power during use of the vibrator element 5102 to the vibrator element 5102, and the process S5-2 of adjusting the frequency of the vibrator element 5102 after the process S5-1 of strongly exciting the vibrator element 5102. According to this, it is possible to reduce the CI value of the vibrator element 5102, and thus it is possible to improve the oscillation rate in the frequency adjustment process S5-2 (refer to “3. Experimental Example” to be described later). Accordingly, it is possible to improve a yield ratio during manufacturing of the vibrator 5100.

In the method of adjusting the frequency of the vibrator 5100 according to this embodiment, in the process S5-1 of strongly exciting the vibrator element 5102, power of 2.5 mW or more to 100 mW or less is applied to the vibrator element 5102. According to this, it is possible to reduce the CI value of the vibrator element 5102, and thus it is possible to improve the oscillation rate (refer to “3. Experimental Example” to be described later).

In the method of adjusting the frequency of the vibrator 5100 according to this embodiment, in the process S5-1 of strongly exciting the vibrator element 5102, power of 10 mW or more to 100 mW or less is applied to the vibrator element 5102. According to this, it is possible to further reduce the CI value of the vibrator element 5102, and thus it is possible to further improve the oscillation rate (refer to “3. Experimental Example” to be described later).

The method of manufacturing the vibrator 5100 according to this embodiment includes the method of adjusting the frequency of the vibrator 5100 according to this embodiment, and thus it is possible to improve a yield ratio during manufacturing.

### 3. Experimental Example

Hereinafter, an experimental example will be described, and the invention will be described in more detail. In addition, the invention is not particularly limited by the following experimental example.

### 3.1 First Experimental Example

With regard to the method of manufacturing the vibrator 5100 described above, an experiment was carried out to investigate a relationship between the drive level during over-drive, and a variation ratio of the CI value before and after the over-drive.

Specifically, in the method of manufacturing the vibrator 5100 described above, the CI value before and after the over-drive was measured with respect to cases where the drive level DL during the over-drive in the strong excitation process S5-1 was 0.1 mW, 0.5 mW, 2.5 mW, 10 mW, and 100 mW, respectively. In addition, the vibrator was set to the AT-cut type vibrator, and an oscillation frequency was set to 16 MHz.

A method of obtaining the variation ratio of the CI value before and after the over-drive will be described in more detail. Here, description will be given of a case where DL is 0.1 mW as an example. First, in the method of manufacturing the vibrator 5100 as described above, a drive level DL of 0.01 mW during typical use was applied to the vibrator element before the strong excitation process S5-1 so as to measure the CI value. Next, in the strong excitation process S5-1, power in a drive level DL of 0.1 mW was applied for 1 second to 30 seconds, thereby strongly exciting the vibrator 5100 (over-drive). Next, a drive level DL of 0.01 mW during typical use was applied again to the vibrator element so as to measure the CI value. In this manner, a variation ratio of the CI value before and after the over-drive was obtained with respect to the case where DL was set to 0.1 mW.

The CI value before and after the over-drive was also measured with respect to other cases where the drive level DL was set to 0.5 mW, 2.5 mW, 10 mW, and 100 mW, respectively by the same method so as to obtain the variation ratio of the CI value before and after the over-drive.

In addition, for reference, the CI value was also measured with respect to a case where the drive level DL in the strong excitation process S5-1 was set to 0.01 mW, that is, a case where a drive level during typical use was applied without the strong excitation.

FIG. 10 is a graph illustrating a relationship between the drive level DL during over-drive, and a variation ratio ((CI2−CI1)/CI1) of a CI value (CI2) after the over-drive to a CI value (CI1) before the over-drive.

As illustrated in FIG. 10, the CI value of the vibrator element after the carrying out the over-drive by applying a drive level DL of 2.5 mW or greater was greatly reduced in comparison to the CI value before carrying out the over-drive. Specifically, after carrying out the over-drive by applying DL of 2.5 mW, the CI value was reduced by 40%. In addition, after carrying out the over-drive by applying DL of 10 mW, the CI value was reduced by 45%. In addition, after carrying out the over-drive by applying DL of 100 mW, the CI value was reduced by 50%. As described above, when the over-drive was carried out by applying a drive level DL as high as 2.5 mW or greater, it could be seen that it enters a state in which the vibrator element is likely to oscillate.

### 3.2 Second Experimental Example

Next, in the method of manufacturing the vibrator 5100 as described above, an experiment of investigating a relationship between the drive level during the over-drive and an oscillation rate after the over-drive was carried out.

Specifically, as is the case with the above-described first experimental example, an oscillation rate was measured with respect to cases where the drive level DL during the over-drive in the strong excitation process S5-1 was set to 0.1 mW, 0.5 mW, 2.5 mW, 10 mW, and 100 mW, respectively. In addition, the vibrator was set to an AT-cut type vibrator, and an oscillation frequency was set to 16 MHz.

In addition, the oscillation rate represents a ratio of normally oscillating vibrator elements to the total measurement number. In addition, the normally oscillating vibrator elements represent vibrator elements in which the CI value at DL of 0.01 mW satisfies negative resistance of an oscillation circuit. Here, an investigation was made whether or not 1000 vibrator elements normally oscillate for each drive level DL.

FIG. 11 is a graph illustrating a relationship between the drive level DL during the over-drive, and the oscillation rate after the over-drive.

As illustrated in FIG. 11, in a case of a drive level DL of 0.01 mW, that is, in a case of not carrying out the over-drive, the oscillation rate was approximately 93%, but in a case of carrying out the over-drive at a drive level DL of 2.5 mW or greater, the oscillation rate becomes 100%.

In addition, in the over-drive in which a drive level DL of 100 mW was applied to the vibrator element, as described above, the CI value was reduced by 50%, and the oscillation rate became 100%, and thus a sufficient effect was obtained. According to this, it is preferable that the over-drive is carried out in a drive level of 100 mW or less so as to realize low power consumption.

In addition, when the method of manufacturing the vibrator as described above includes a vibrator formation process of forming the vibrator element 5102 before the vibrator element mounting process S1, and a joining process of connecting a semiconductor device 700 to be described later to the base 5112 at a position not interfering with the vibrator element 5102 through a joining member 510 to be described later before the sealing process S7, the above-described method becomes a method of manufacturing an oscillator.

According to this, the method of manufacturing the oscillator as described above includes a vibrator element formation process of forming the vibrator element 5102, a joining process of joining the base 5112 and the vibrator element 5102 through a joining member (conductive adhesive 5134a) (vibrator element mounting process S1), a strong excitation process of applying power, which is higher than drive power during use of the vibrator element 5102, to the vibrator element 5102 (strong excitation process S5-1), and a joining process of connecting the semiconductor device 700 to the base 5112 through the joining member 510.

In the method of manufacturing the oscillator as described above, as is the case with the method of manufacturing the vibrator, it is possible to reduce the CI value of the vibrator element 5102, and thus it is possible to improve a yield ratio during manufacturing.

### Second Embodiment

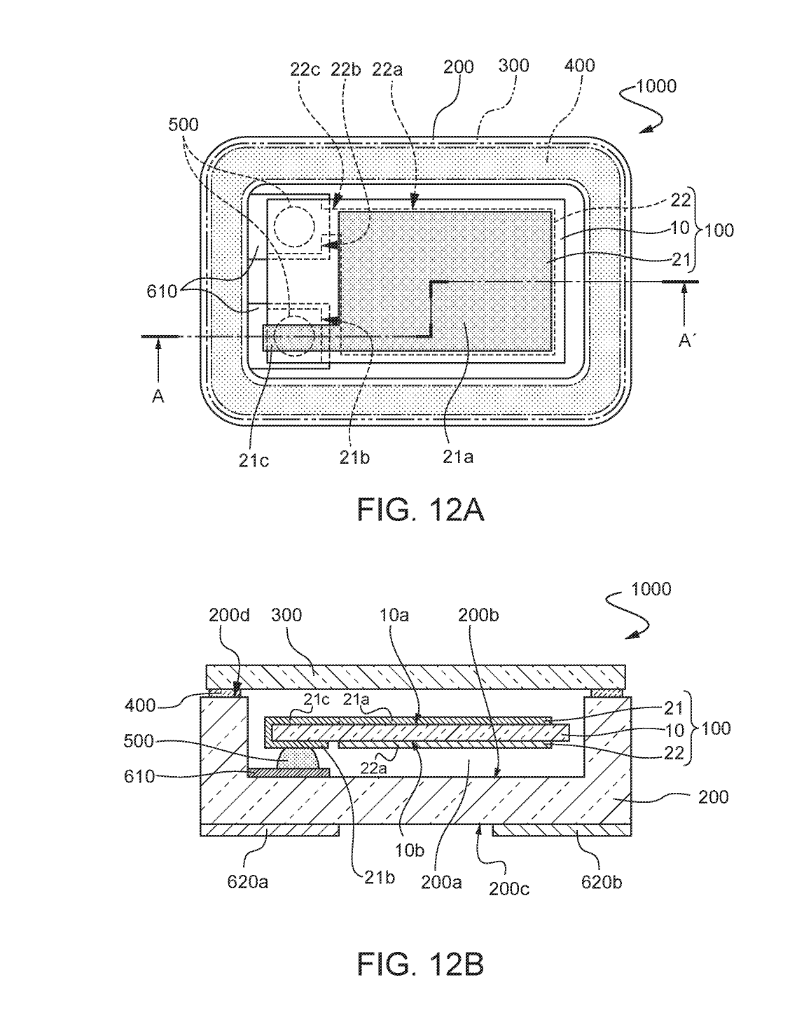

FIGS. 12A and 12B illustrate a schematic configuration of a vibrator that is obtained by the method of manufacturing the vibrator (example of a vibration device) according to the second embodiment. FIG. 12A is an external appearance plan view in which a lead is omitted, and FIG. 12B is a cross-sectional view taken along line A-A′ in FIG. 12A.

As illustrated in FIG. 12B, a vibrator 1000 illustrated in FIGS. 12A and 12B includes a vibrator element 100, a package (corresponding to the base in the first embodiment) 200 having a concave portion space 200a capable of accommodating the vibrator element 100, a lead 300, and a seal member 400 that joins the package 200 and the lead 300 so as to tightly seal the concave portion space 200a.

The vibrator element 100 includes a piezoelectric element 10, a first electrode 21 that is formed on a first main surface 10a of the piezoelectric element 10, and a second electrode 22 that is formed on a second main surface 10b of the piezoelectric element 10. With regard to the piezoelectric element 10, there is no particular limitation as long as the piezoelectric element 10 is formed from a material such as quartz crystal, ceramic, and PZT which have piezoelectric properties, and in this embodiment, description will be made with reference to the quartz crystal. Hereinafter, the piezoelectric element 10 is referred to as a quartz crystal element 10.

As illustrated in FIG. 12A, the first electrode 21 includes an excitation electrode 21a which is formed on the first main surface 10a and has an approximately rectangular planar shape in this embodiment, a connection electrode 21b that is formed on the second main surface 10b that is a rear surface of the first main surface 10a, and an extension portion 21c that connects the excitation electrode 21a and the connection electrode 21b. In addition, the second electrode 22 includes an excitation electrode 22a which is formed on the second main surface 10b and has an approximately rectangular planar shape in this embodiment to overlap the excitation electrode 21a which is formed on the first main surface 10a in a plan view, a connection electrode 22b, and an extension portion 22c that connects the excitation electrode 22a and the connection electrode 22b.

The package 200 has insulating properties. For example, the package 200 is formed from ceramic, a resin, glass, and the like. Connection electrodes 610 are formed on the bottom 200b of the concave portion space 200a of the package 200, and external connection electrodes 620a and 620b, which are electrically connected to the connection electrodes 610 through an interconnection (not illustrated) formed on an inner side of the package 200, are formed on an external bottom surface 200c of the package 200.

In the vibrator element 100, the connection electrodes 21b and 22b are arranged in the concave portion space 200a of the package 200 to face the connection electrodes 610 and are connected thereto by a joining member 500 having conductivity. In addition, the lead 300 is fixed to an upper end surface 200d having a frame-shaped planar shape on an opening side of the concave portion space 200a of the package 200 through the seal member 400, and thus the concave portion space 200a is air-tightly sealed. In addition, for example, it is preferable that the concave portion space 200a is, for example, vacuum-sealed or filled with an inert gas, and is air-tightly sealed.

As described above, as the vibrator element 100 that is provided to the vibrator 1000 according to this embodiment, as illustrated in FIGS. 12A and 12B, a so-called AT vibrator element is exemplified, but there is no limitation thereto, and the vibrator element 100 may be, for example, a tuning fork type vibrator element and the like, or a gyro element.

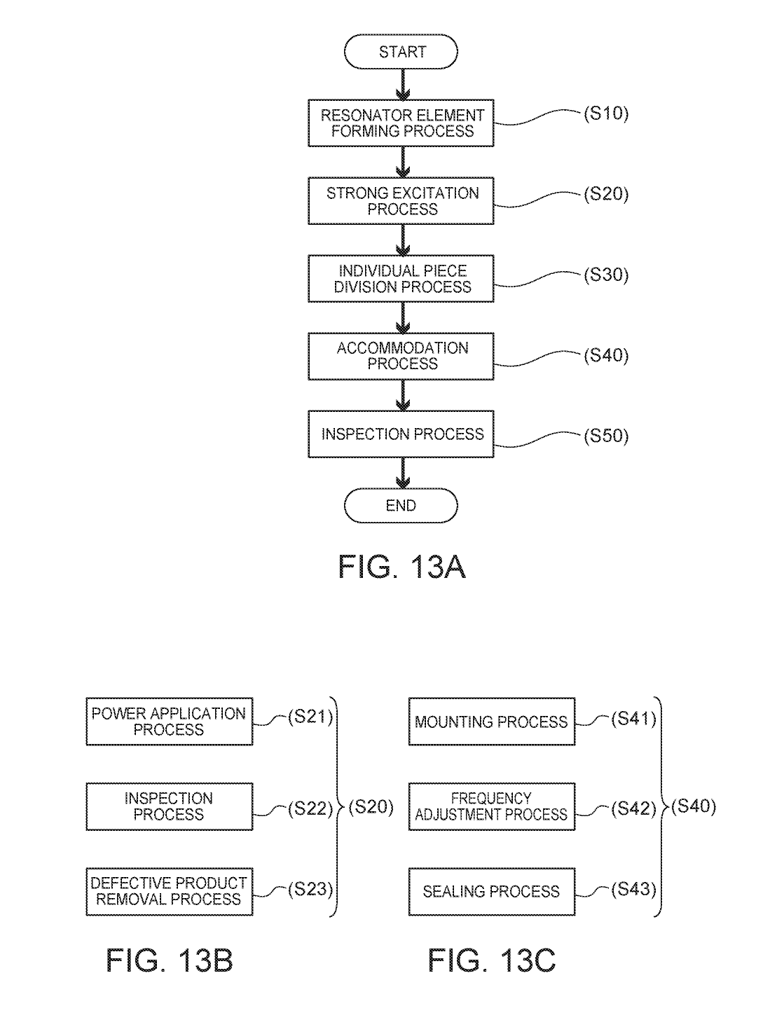

FIGS. 13A to 13C are flowcharts illustrating a method of manufacturing the vibrator 1000 as described above. FIG. 13A illustrates a method of manufacturing a vibrator according to the second embodiment, FIG. 13B illustrates details of a strong excitation process (S20) illustrated in FIG. 13A, and FIG. 13C is a flowchart illustrating details of an accommodation process (S40) illustrated in FIG. 13A.

As illustrated in FIG. 13A, the method of manufacturing the vibrator 1000 according to this embodiment starts from a vibrator element forming process (S10).

### Vibrator Element Forming Process

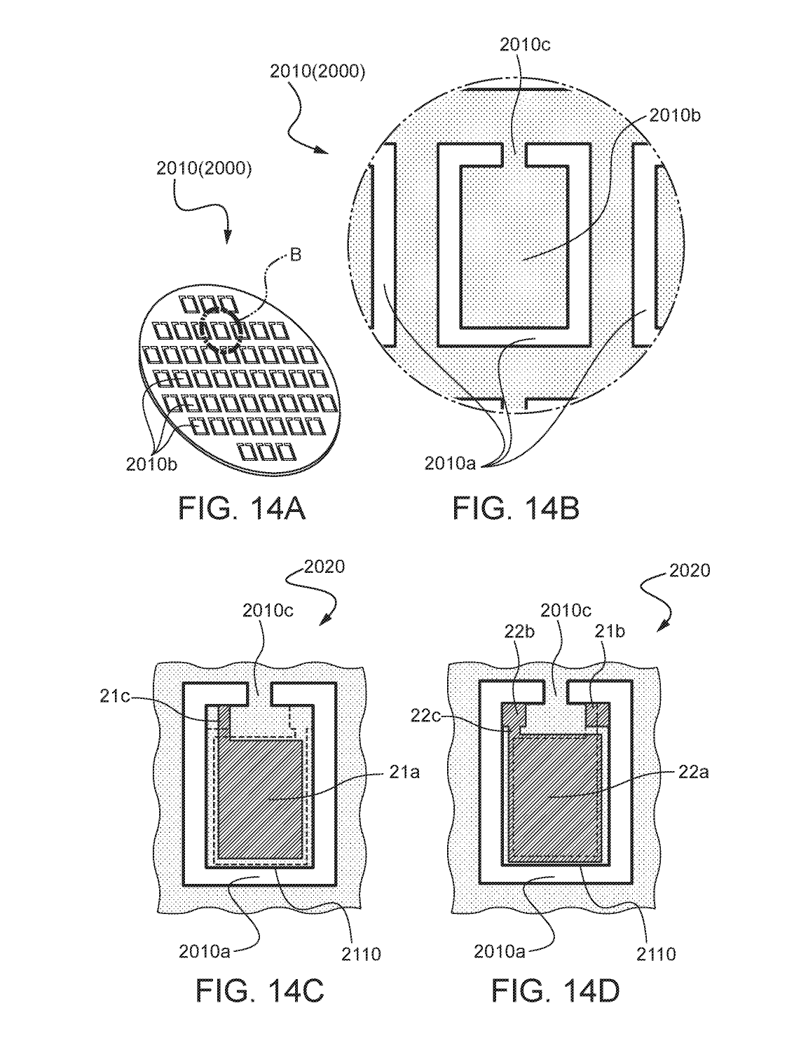

As illustrated in FIG. 14A, in the vibrator element forming process (S10), a disc like quartz crystal substrate 2000 (example of a substrate) having a predetermined thickness, that is, a so-called quartz crystal wafer is prepared. Hereinafter, the quartz crystal substrate 2000 is referred to as a wafer 2000.

As illustrated in FIG. 14B that is an enlarged view of a B portion illustrated in FIG. 14A, for example, a plurality of penetration portions 2010a are formed in the wafer 2000 through patterning and etching by photolithography. When the penetration portions 2010a are formed, a vibration element wafer 2010, in which a plurality of quartz crystal element portions 2010b, and a plurality of breaking-off portions 2010c as connection portions with the wafer 2000, is obtained.

The vibrator element forming process (S10) is carried out to obtain a first vibrator element wafer 2020 including a plurality of first vibrator element portions 2110. In the vibrator element forming process (S10), a conductive metal film is formed on a surface of the vibration element wafer 2010 through deposition or sputtering, and as illustrated in FIG. 14C, the first electrode 21 is formed on one surface of each of the quartz crystal element portions 2010b which are formed in the vibration element wafer 2010 through patterning and etching by photolithography. In addition, as illustrated in FIG. 14D, the second electrode 22 and the connection electrode 21b of the first electrode 21 are formed on the other surface of the quartz crystal element portion 2010b.

### Strong Excitation Process

As illustrated in FIGS. 14C and 14D, the first vibrator element wafer 2020, which is obtained by the vibrator element forming process (S10) and includes the plurality of first vibrator element portions 2110 in which the first electrode 21 and the second electrode 22 are formed, is subjected to the strong excitation process (S20). As illustrated in FIG. 13B, the strong excitation process (S20) includes a power application process (S21), an inspection process (S22), and a defective product removal process (S23).

### Power Application Process

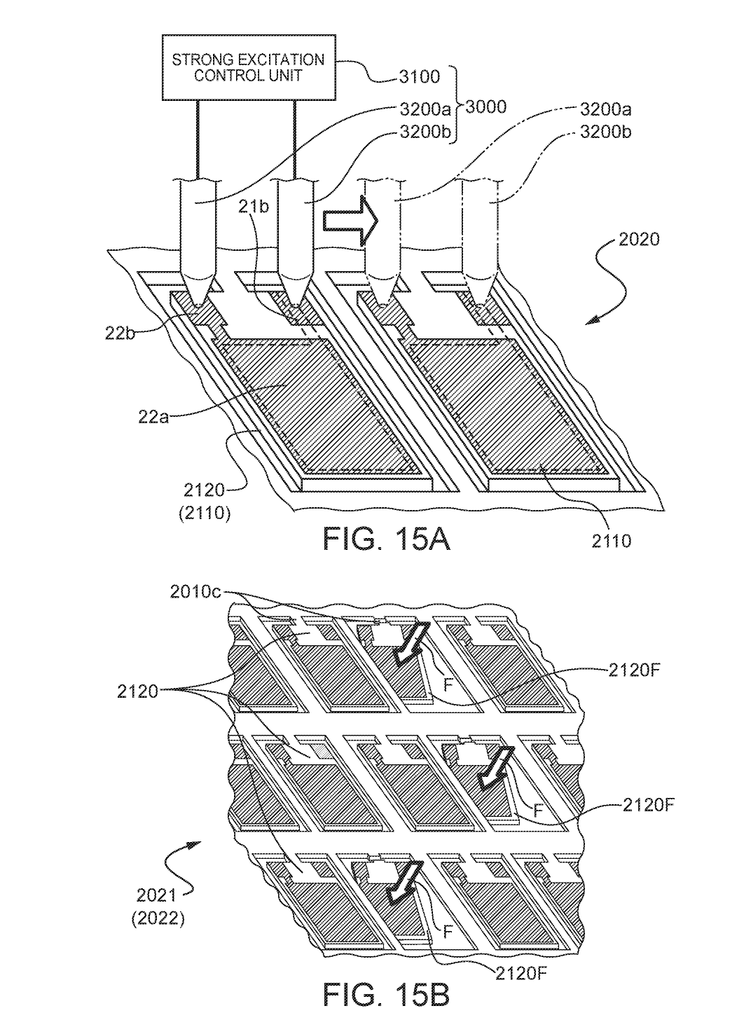

First, as illustrated in FIG. 15A, in the power application process (S21), connection terminals 3200a and 3200b, which are connected to a strong excitation control unit 3100 provided to a strong excitation device 3000, are brought into contact with the connection electrodes 21b and 22b, respectively, and predetermined large power is applied to the first electrode 21 and the second electrode 22 by the strong excitation control unit 3100. In addition, vibration with a large amplitude is excited in each of the first vibrator element portions 2110 due to large power supplied to the excitation electrodes 21a and 22a, and thus at least a part of foreign matter adhered to the first electrode 21 and the second electrode 22 is shaken off. In addition, it is possible to improve adhesiveness between the quartz crystal element 10 and the electrodes 21 and 22.

After applying the predetermined large power is applied to the first vibrator element portion 2110 for predetermined time, the connection terminals 3200a and 3200b are separated from the connection electrodes 21b and 22b. According to this, the power application process (S21) with respect to the first vibrator element portion 2110 is terminated, and a second vibrator element portion 2120 is formed. Then, the connection terminals 3200a and 3200b are moved to a next one of the first vibrator element portions 2110, and the power application process (S21) is carried out. In this manner, the power application process (S21) is sequentially carried out with respect to the entirety of the first vibrator element portions 2110 which are provided to the first vibrator element wafer 2020, thereby obtaining a second vibrator element wafer 2021 including a plurality of the second vibrator element portions 2120. Then, the process transitions to the inspection process (S22).

### Inspection Process

Since occurrence of breakage is predicted in a part of the second vibrator element portion 2120 due to application of power, which is higher than predetermined operation power of the second vibrator element portions 2120, in the power application process (S21), the inspection process (S22) inspects whether or not a predetermined operation is obtained. Although not illustrated, in the inspection process (S22), inspection terminals, which are connected to an inspection device, are brought into contact with the connection electrodes 21b and 22b to apply predetermined power to the connection electrodes 21b and 22b, thereby causing excitation. From an oscillation signal that is obtained, a predetermined quality, for example, a frequency equivalent series resistance value and the like are detected to determine whether or not the quality is good or bad.

### Defective Product Removal Process

The second vibrator element wafer 2021, of which the individual second vibrator element portions 2120 are subjected to the quality determination in the inspection process (S22), is subjected to the defective product removal process (S23). As illustrated in FIG. 15B, in the defective product removal process (S23), a defective vibrator element portion 2120F, which is determined as a bad quality, is cut out from a cut-out portion 2010c, and is removed from the second vibrator element wafer 2021. When the defective vibrator element portion 2120F is determined as a bad quality in the above-described inspection process (S22), position information of the defective vibrator element portion 2120F of the second vibrator element wafer 2021 in the vibrator element wafer 2020 is stored in an inspection device (not illustrated), and a pressing force F in an illustrated arrow direction is applied by a pressing unit (not illustrated). A cut-out portion 2010c with the weakest strength in the detective vibrator element portion 2120F, to which the pressing force F is applied, is fractured, and thus the defective vibrator element portion 2120F is detached and removed from the second vibrator element wafer 2021. In addition, in the detective product removal process, a mark that is recognizable with an image recognition method may be formed on a surface of the detective vibrator element portion 2120F by using ink, a laser, and the like instead of removing the defective vibrator element portion 2120F from the second vibrator element wafer 2021.

As described above, the strong excitation process (S20) including the power application process (S21), the inspection process (S22), and the defective product removal process (S23) is carried out, and a second vibrator element wafer 2022, in which a plurality of the second vibrator element portions 2120 with a good quality are formed, is subjected to the subsequent individual piece division process (S30).

### Individual Piece Division Process

As is the case with the above-described defective product removal process (S23), the individual piece division process (S30) is a process of applying a pressing force F to each of the second vibrator element portions 2120 to fracture the cut-out portion 2010c from the second vibrator element wafer 2022 including the second vibrator element portions 2120 with a good quality, thereby taking out individual pieces of the vibrator elements 100. Each of the vibrator elements 100, which are divided into individual pieces in the individual piece division process (S30), is subjected to the accommodation process (S40). In addition, in a case where a mark that is recognizable with an image recognition method is formed on the surface of the detective vibrator element portion 2120F by using ink, a laser, and the like in the defective product removal process (S23), image recognition is carried out in the process of division into individual pieces, and the defective vibrator element portion 2120F is not taken out.

### Accommodation Process

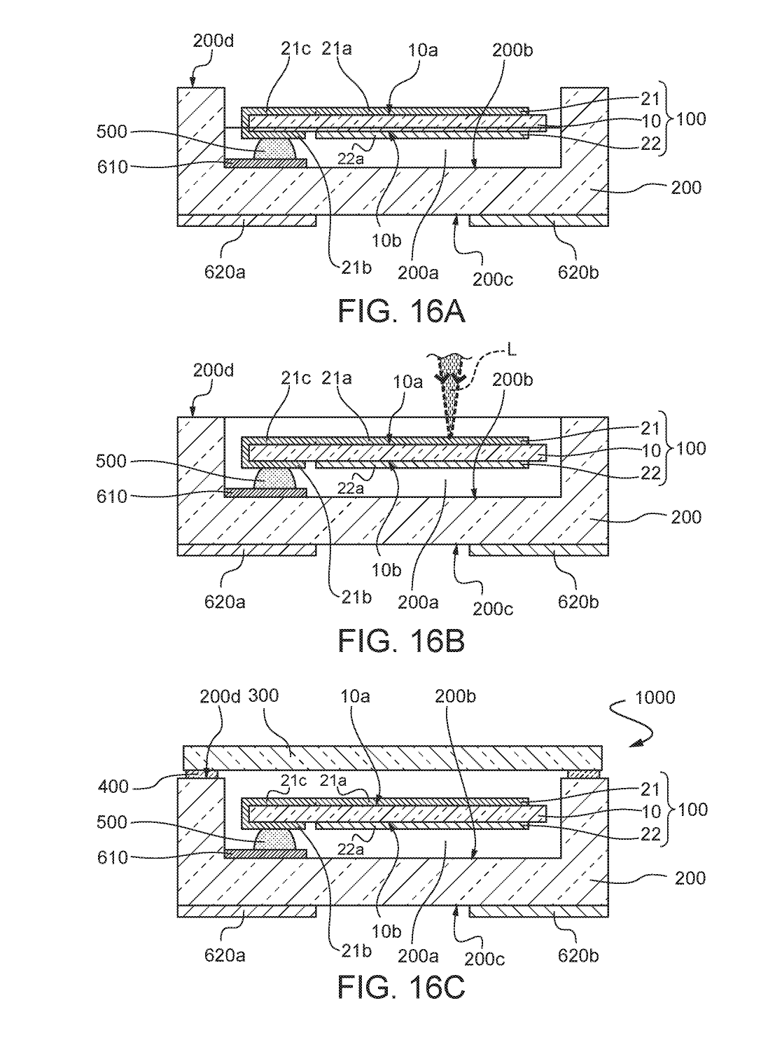

The accommodation process (S40) is a process of obtaining the vibrator 1000 (refer to FIGS. 12A and 12B) through so-called packaging. The accommodation process (S40) includes a mounting process (S41), a frequency adjustment process (S42), and a sealing process (S43). FIGS. 16A to 16C illustrate a manufacturing process that is the accommodation process (S40), and cross-sectional views of a portion taken along line A-A′ in FIG. 12A. The same reference numerals will be given to the same constituent elements as in the vibrator 1000 illustrated in FIGS. 12A and 12B, and description thereof will not be repeated.

### Mounting Process

In the accommodation process (S40), first, mounting process (S41) is carried out. As illustrated in FIG. 16A, in the mounting process (S41), the joining member 500 having conductivity is arranged on each of the connection electrodes 610 which are formed on the bottom 200b of the concave portion space 200a of the package 200. In addition, the vibrator element 100 is disposed in the concave portion space 200a in such a manner that each of the connection electrodes 21b and 22b of the vibrator element 100 is placed on the joining member 500 on each of the connection electrode 610 so as to face the connection electrode 610. Then, when the joining member 500 is cured to electrically connect each of the connection electrodes 610 and each of the connection electrodes 21b and 22b of the vibrator element 100, and to fix the vibrator element 100 to the package 200, the mounting process (S41) is terminated. In addition, the joining member 500 is not particularly limited and examples thereof include a conductive adhesive, solder, a metal bump, and the like. Among these, the conductive adhesive with high productivity is appropriately used.

### Frequency Adjustment Process

When the vibrator element 100 is mounted in the concave portion space 200a of the package 200 through the mounting process (S41), the process transitions to the frequency adjustment process (S42). As illustrated in FIG. 16B, in the frequency adjustment process (S42), a laser L is emitted from a laser irradiation device (not illustrated) toward the excitation electrode 21a of the first electrode 21 in a direction from an opening side of the concave portion space 200a of the package 200, and a part of an electrode metal of the excitation electrode 21a transpires and is removed due to the laser L before reaching a predetermined vibration frequency. In addition, in addition to the above-described method, the frequency adjustment process (S42) may be carried out by irradiating the excitation electrode 21a with ions, plasma, and the like, or may be carried out by applying a member such as Au, Ag, and Al to the excitation electrode 21a by a method such as deposition and sputtering.

### Sealing Process

The package 200, on which the vibrator element 100 adjusted to a predetermined frequency through the frequency adjustment process (S42) is mounted, is subjected to the sealing process (S43). As illustrated in FIG. 16C, in the sealing process (S43), first, the seal member 400 is placed on the upper end surface 200d, which has a frame-shaped planar shape, on an opening side of the concave portion space 200a of the package 200, and the lead 300 is further placed on the seal member 400. In addition, as the seal member 400, a material having a thermal expansion coefficient close to that of the package 200, for example, Kovar is appropriately used. In addition, as the lead 300, for example, Kovar having a thermal expansion coefficient close to that of the package 200 and the seal member 400 is appropriately used. In addition, as the package 200, a package in which the seal member 400 is placed on the upper end surface 200d in advance may be used.

In addition, in a processing room (chamber) (not illustrated) which is maintained to a vacuum environment or an inert gas atmosphere environment, the lead 300 and the package 200 are air-tightly joined by a joining method such as seam welding. In this state, the sealing process (S43) is terminated, the accommodation process (S40) is terminated, and the vibrator 1000 is obtained. Then, the process transitions to the inspection process (S50).

### Inspection Process

In the inspection process (S50), inspection is carried out on the basis of predetermined specifications of the vibrator 1000 as a finished product. Although not illustrated, in the inspection process (S50), predetermined functional quality inspection, which is carried out by bringing terminals provided to an inspection device into contact with the external connection electrodes 620a and 620b, external appearance inspection with the naked eye or a microscope, and the like are carried out for quality determination.

With regard to a vibrator in the related art, there is also known a method of carrying out strong excitation, that is, so-called over-drive to improve adhesiveness between an excitation electrode and an element piece, but the strong excitation is typically carried out after sealing a vibrator element in a package. According to this method in the related art, foreign matter adhered to the vibrator element are shaken off into a sealed package inner space due to strong excitation, and thus the foreign matter collected in the package inner space are repetitively adhered to and detached from the vibrator element. Therefore, the repetitive adhesion and detachment become a cause for a variation in vibration characteristics of the vibrator element.

However, in the method of manufacturing the vibrator 1000 according to the second embodiment, the strong excitation process (S20) is carried out in a state of the vibrator element wafer 2020, and thus at least a part of foreign matter adhered to the vibrator element 100 is shaken off. According to this, it is possible to reduce a possibility that the foreign matter adhered to the vibrator element 100 are introduced into the package 200. Accordingly, it is possible to obtain the vibrator 1000 having stable vibration characteristics. In addition, when the strong excitation process (S20) of the second embodiment is carried out under the same conditions as in the strong excitation process (S5-1) of the first embodiment, the same effect as in the first embodiment is obtained.

### Third Embodiment

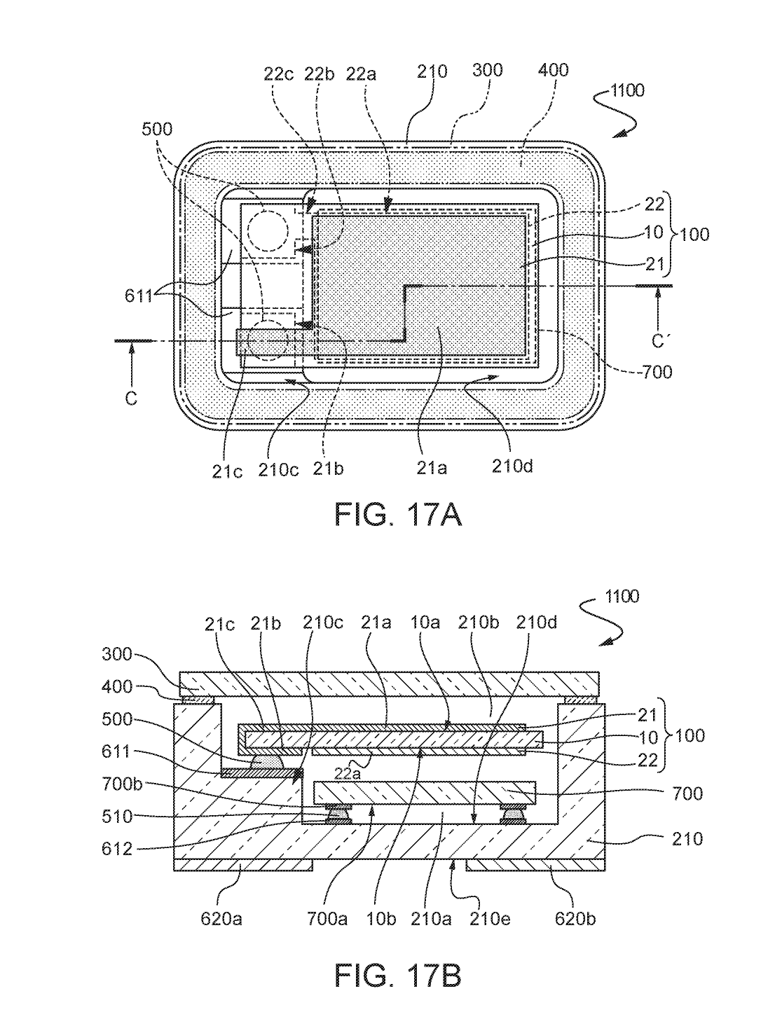

FIGS. 17A and 17B illustrate a schematic configuration of an oscillator that is obtained by a method of manufacturing an oscillator (example of the vibration device) according to a third embodiment. FIG. 17A is an external appearance plan view in which the lead is omitted, and FIG. 17B is a cross-sectional view taken along line C-C′ in FIG. 17A. An oscillator 1100 illustrated in FIG. 17 includes the vibrator element 100 provided to the vibrator 1000 according to the second embodiment, and a semiconductor device including an oscillation circuit of the vibrator element 100, and thus the same reference numerals will be given to the same constituent elements in the vibrator 1000 according to the second embodiment and the manufacturing method thereof, and description thereof will not be repeated.

As illustrated in FIG. 17B, the oscillator 1100 illustrated in FIGS. 17A and 17B includes a vibrator element 100, a semiconductor device 700 (hereinafter, referred to as “IC 700”), a package (base) 210 including a first concave portion space 210a capable of accommodating the IC 700, and a second concave portion space 210b which is connected to the first concave portion space 210a and is capable of accommodating the vibrator element 100, a lead 300, and a seal member 400 which joins the package 210 and the lead 300, thereby closely sealing the concave portion spaces 210a and 210b.

The IC 700 includes an external electrode 700b which is formed on one surface 700a of the IC 700 and is electrically connected to an electronic circuit (not illustrated) that is formed inside the IC 700. The external electrode 700b is disposed over an IC connection electrode 612, which is formed on the bottom 210d of the first concave portion space 210a of the package 210, to face the external electrode 700b of the IC 700, and is joined to the external electrode 700b through a joining member 510 having conductivity. According to this, the IC 700 is accommodated in the first concave portion space 210a of the package 210.

With regard to the vibrator element 100, each of connection electrodes 21b and 22b is arranged to face each of connection electrodes 611 which are formed on a stepped portion 210c that becomes the bottom of the second concave portion space 210b of the package 210, and is fixed and arranged by the joining member 500 having conductivity. In addition, the connection electrode 611 and the IC connection electrode 612 are electrically connected through an arrangement interconnection (not illustrated) that is formed inside the package 210. In addition, the IC connection electrode 612 is electrically connected to external connection electrodes 620a and 620b, which are formed on an external bottom surface 210e of the package 210, through an arrangement interconnection (not illustrated) that is formed inside the package 210.

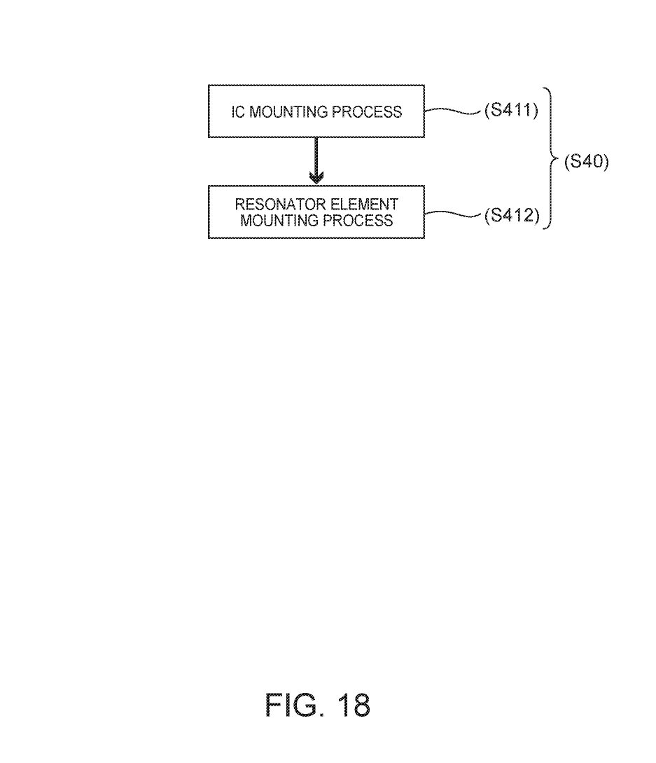

Next, description will be given of a method of manufacturing the oscillator 1100. The method of manufacturing the oscillator 1100 according to this embodiment includes the same processes in the method of manufacturing the vibrator 1000 according to the second embodiment, that is, the same processes as in the flowchart illustrated in FIGS. 13A to 13C. However, a configuration of the mounting process (S41) included in the accommodation process (S40) illustrated in FIG. 13C is different in each case, and FIG. 18 illustrates a flowchart of a process that is included in the mounting process (S41). In addition, as described above, in the method of manufacturing the oscillator 1100 according to the third embodiment, description of the same processes as in the method of manufacturing the vibrator 1000 according to the second embodiment will not be repeated.

### From Vibrator Element Forming Process to Individual Piece Division Process

The oscillator 1100, which is obtained by the manufacturing method according to this embodiment, includes the vibrator element 100 that is provided to the vibrator 1000 that is obtained by the manufacturing method according to the second embodiment. Accordingly, processes from the vibrator element forming process (S10) to the individual piece division process (S30) are the same between the second embodiment and the third embodiment illustrated in FIG. 13A. Accordingly, description thereof will not be repeated.

### Accommodation Process

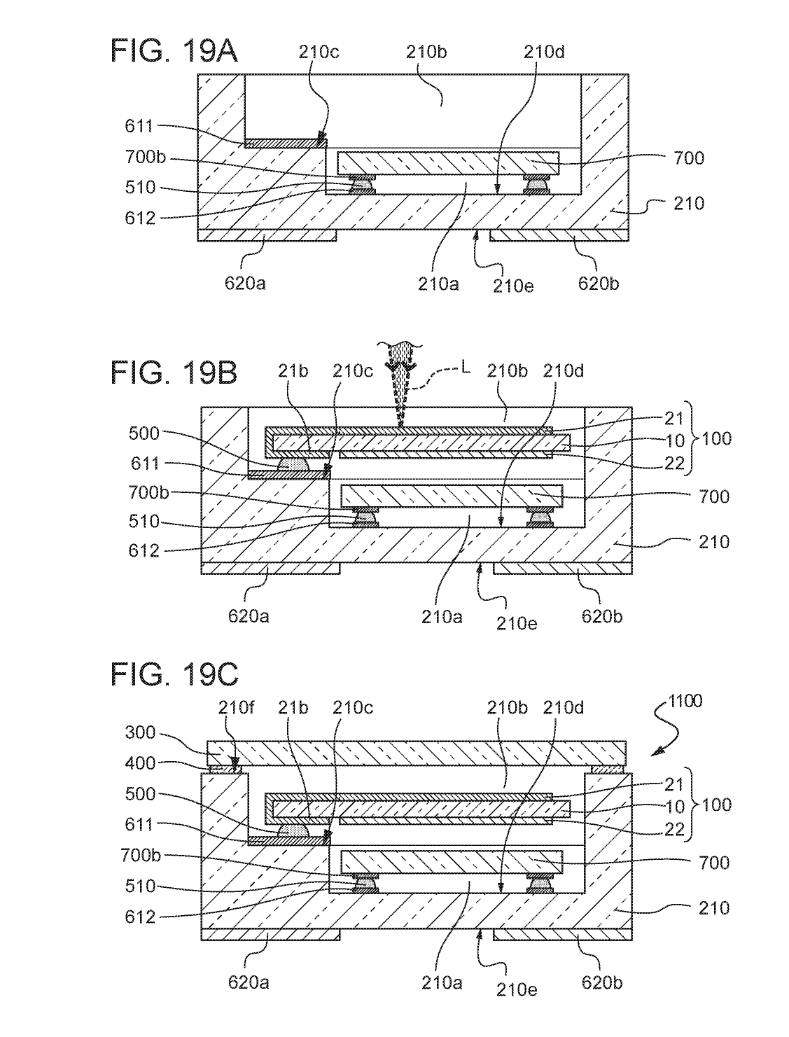

An accommodation process (S40) is a process of obtaining the oscillator 1100 (refer to FIGS. 17A and 17B) through so-called packaging. The accommodation process (S40) includes a mounting process (joining process) (S41), a frequency adjustment process (S42), and a sealing process (S43). In addition, the mounting process (S41) includes an IC mounting process (S411), and a vibrator element mounting process (S412). FIGS. 19A to 19C are cross-sectional views of a portion taken along line C-C′ in FIG. 17A which illustrates the manufacturing process of the mounting process (S41) included in the accommodation process (S40). The same reference numerals will be given to the same constituent elements as in the oscillator 1100 illustrated in FIGS. 17A and 17B, and description thereof will not be repeated.

### IC Mounting Process

In the mounting process (S41), first, the IC mounting process (S411) is carried out. As illustrated in FIG. 19A, in the IC mounting process (S411), a joining member 510 having conductivity is arranged in advance on the IC connection electrode 612 that is formed on the bottom 210d of the first concave portion space 210a of the package 210, and the external electrode 700b of the IC 700, which is prepared in advance, is placed on the joining member 510 to face the IC connection electrode 612. Then, when the joining member 510 is cured to electrically connect the IC connection electrode 612 and the external electrode 700b of the IC 700 to each other, and to fix the IC 700 to the package 210, the IC mounting process (S411) is terminated. In addition, in the IC mounting process (S411), the IC connection electrode 612 and the external electrode 700b may be electrically connected to each other by arranging the joining member 510 on the external electrode 700b of the IC 700, and joining the joining member 510 and the IC connection electrode 612 to each other. In addition, in addition to the above-described method, after disposing the IC 700 in such a manner that a surface on which the external electrode 700b is not formed, and the bottom 210d of the first concave portion space 210a of the package 210 face each other, the external electrode 700b and the IC connection electrode 612 may be electrically connected to each other through a bonding wire.

### Vibrator Element Mounting Process

After the IC mounting process (S411), the process transitions to the vibrator element mounting process (S412). As illustrated in FIG. 19B, in the vibrator element mounting process (S412), first, the joining member 500 having conductivity is arranged on the connection electrode 611 that is formed on the stepped portion 210c that becomes the bottom of the second concave portion space 210b of the package 210. Next, the vibrator element 100 is accommodated in the second concave portion space 210b in such a manner that each of the connection electrodes 21b and 22b which are provided to the vibrator element 100 faces each of the connection electrodes 611, and the vibrator element 100 is placed on the stepped portion 210c in such a manner that each of the connection electrodes 21b and 22b comes into contact with the joining member 500. Then, when the joining member 500 is cured to electrically connect each of the connection electrodes 611 and each of the connection electrodes 21b and 22b of the vibrator element 100, and to fix the vibrator element 100 to the package 210, the vibrator element mounting process (S412) is terminated.

After carrying out the mounting process (S41) including the IC mounting process (S411) and the vibrator element mounting process (S412), the process transitions to the frequency adjustment process (S42).

### Frequency Adjustment Process and Sealing Process

The frequency adjustment process (S42) and the sealing process (S43) are the same as in the method of manufacturing the vibrator 1000 according to the second embodiment. As illustrated in FIG. 19B, in the frequency adjustment process (S42) according to this embodiment, the excitation electrode 21a of the first electrode 21 of the vibrator element 100, which is accommodated in the package 210, is irradiated with a laser L to transpire and remove a part of the excitation electrode 21a. According to this, the vibrator element 100 is adjusted to a predetermined frequency.

After the frequency adjustment process (S42), the process transitions to the sealing process (S43). As illustrated in FIG. 19C, in the sealing process (S43), first, the seal member 400 is placed on an upper end surface 210f having a frame-shaped planar shape on an opening side of the second concave portion space 210b of the package 210, and the lead 300 is further placed on the seal member 400. In addition, in a processing room (chamber) (not illustrated) which is maintained to a vacuum environment or an inert gas atmosphere environment, the lead 300 and the package 210 are air-tightly joined by a joining method such as seam welding. In this state, the sealing process (S43) is terminated, and the oscillator 1100 is obtained. Then, the process transitions to an inspection process (S50).

### Inspection Process

After the accommodation process (S40) including the mounting process (S41), the frequency adjustment process (S42), and the sealing process (S43), the process transitions to the inspection process (S50). In the inspection process (S50), inspection is carried out on the basis of predetermined specifications of the oscillator 1100 as a finished product. Although not illustrated, in the inspection process (S50), predetermined functional quality inspection, which is carried out by bringing terminals provided to an inspection device into contact with the external connection electrodes 620a and 620b, external appearance inspection with the naked eye or a microscope, and the like are carried out for quality determination.

In the method of manufacturing the oscillator 1100 according to the third embodiment as described above, the strong excitation process (S20) is carried out in a state of the vibrator element wafer 2020, and thus at least a part of foreign matter adhered to the vibrator element 100 is shaken off. According to this, it is possible to reduce a possibility that the foreign matter adhered to the vibrator element 100 are introduced into the package 210. Accordingly, it is possible to obtain the oscillator 1100 having stable vibration characteristics.

In addition, in the related art, in a case of an oscillator in which the strong excitation is typically carried out after sealing a semiconductor device (IC) and a vibrator element in a package, large power for strong excitation also flows to the semiconductor device, and thus there is a concern that the semiconductor device may be broken. However, in the method of manufacturing the oscillator 1100 according to this embodiment, the strong excitation process (S20) is carried out at a part stage of the vibrator element 100, and thus it is possible to obtain a stable-quality oscillator 1100 in which the IC 700 to be mounted in the accommodation process (S40) after the strong excitation process (S20) is not affected by the strong excitation at all. In addition, when the strong excitation process (S20) of the third embodiment is carried out under the same conditions as in the strong excitation process (S5-1) of the first embodiment, the same effect as in the first embodiment is obtained.

In addition, in the method of manufacturing the vibrator 1000 according to the second embodiment, and in the method of manufacturing the oscillator 1100 according to the third embodiment, large power for the strong excitation is applied to the first vibrator element portion 2110 in a type of the vibrator element wafer 2020 (refer to FIGS. 15A and 15B). In addition, the defective vibrator element portion 2120F, which occurs due to the strong excitation, can be detected in a part state as illustrated.

That is, as disclosed in the related art (for example, JP-A-2004-297737), in a type in which a vibrator element, or the vibrator element and an IC chip are disposed in a cavity, and the vibrator element is strongly excited, in a case where the vibrator element or the IC chip malfunctions due to the strong excitation, a defective loss is added to the cost of the vibrator element, thereby leading a large loss cost including the part cost of the package, the IC, and the like other than the vibrator element, and the number of processing processes (processing cost). However, according to the above-described manufacturing methods, it is possible to avoid the loss cost.

The above-described embodiments are illustrative only, and various modifications can be made without limitation thereto. For example, in the above-described embodiments, as an example of the substrate, the quartz crystal is used as a material having piezoelectric properties, but a silicon semiconductor substrate may be used without limitation thereto. In a case of using the silicon semiconductor substrate as the substrate, electrostatic operation with Coulomb's force may be used as excitation means.

The invention includes a configuration (for example, a configuration in which a function, a method, and a result are the same, or a configuration in which an object and an effect are the same) that is substantially the same as the configuration described in the embodiments. In addition, the invention includes a configuration in which non-essential portions of the configuration described in the embodiments are substituted with other portions. In addition, the invention includes a configuration capable of exhibiting the same operational effect as in the configuration described in the embodiments, and a configuration capable of accomplishing the same object. In addition, the invention includes a configuration in which a technology of the related art is added to the configuration described in the embodiments.

The entire disclosure of Japanese Patent Application Nos. 2015-019619, filed Feb. 3, 2015 and 2015-055792, filed Mar. 19, 2015 are expressly incorporated by reference herein.

What is claimed is:

1. A method of manufacturing a vibration device, comprising:
strongly exciting a vibrator element by applying power, which is higher than drive power during use of the vibrator element, to the vibrator element; and
adjusting a frequency of the vibrator element after the strongly exciting of the vibrator element.

2. The method of manufacturing a vibration device according to claim 1, further comprising:
forming the vibrator element in a substrate before the strongly exciting of the vibrator element.

3. The method of manufacturing a vibration device according to claim 2,
wherein the strongly exciting of the vibrator element includes inspecting the vibrator element.

4. The method of manufacturing a vibration device according to claim 2,
a plurality of the vibrator elements are formed in the substrate.

5. The method of manufacturing a vibration device according to claim 3,
a plurality of the vibrator elements are formed in the substrate.

6. The method of manufacturing a vibration device according to claim 4,
the strongly exciting of the vibrator element is carried out with respect to the plurality of vibrator elements which are formed in the substrate.

7. The method of manufacturing a vibration device according to claim 5,
wherein the strongly exciting of the vibrator element is carried out with respect to the plurality of vibrator elements which are formed in the substrate.

8. The method of manufacturing a vibration device according to claim 1, further comprising:
joining the base and the vibrator element through a joining member before the strongly exciting of the vibrator element.

9. The method of manufacturing a vibration device according to claim 1,
wherein in the strongly exciting of the vibrator element, power of 2.5 mW or more to 100 mW or less is applied to the vibrator element.

10. The method of manufacturing a vibration device according to claim 2,
wherein in the strongly exciting of the vibrator element, power of 2.5 mW or more to 100 mW or less is applied to the vibrator element.

11. The method of manufacturing a vibration device according to claim 4,
wherein in the strongly exciting of the vibrator element, power of 2.5 mW or more to 100 mW or less is applied to the vibrator element.

12. The method of manufacturing a vibration device according to claim 8,
wherein in the strongly exciting of the vibrator element, power of 2.5 mW or more to 100 mW or less is applied to the vibrator element.

13. The method of manufacturing a vibration device according to claim 1,
wherein the vibrator element includes a quartz crystal substrate including a vibration portion that vibrates with thickness shear vibration.

14. The method of manufacturing a vibration device according to claim 2,
wherein the vibrator element includes a quartz crystal substrate including a vibration portion that vibrates with thickness shear vibration.

15. The method of manufacturing a vibration device according to claim 4,
wherein the vibrator element includes a quartz crystal substrate including a vibration portion that vibrates with thickness shear vibration.

16. The method of manufacturing a vibration device according to claim 8,
wherein the vibrator element includes a quartz crystal substrate including a vibration portion that vibrates with thickness shear vibration.

17. A method of manufacturing a vibration device, comprising:
forming a vibrator element;
joining a base and the vibrator element through a joining member;
joining the base and a semiconductor device through a joining member; and
applying power, which is higher than drive power during use of the vibrator element, to the vibrator element for strongly exciting before the joining of the semiconductor device.
